(19) United States
(12) Patent Application Publication
(10) Pub. No.: US 2010/0117224 A1
(43) Pub. Date: May 13, 2010

(54) Sensor

(75) Inventors: Simon J. S. McElrea, Scotts Valley, CA (US); Marc E. Robinson, San Jose, CA (US)

Correspondence Address: HAYNES BEFFEL & WOLFELD LLP, P O BOX 366, HALF MOON BAY, CA, 94019, US

(73) Assignee: Vertical Circuits, Inc., Scotts Valley, CA (US)

(21) Appl. No.: 12/638,870

(22) Filed: Dec. 15, 2009

Related U.S. Application Data
(63) Continuation-in-part of application No. 12/550,012, filed on Aug. 28, 2009.
(60) Provisional application No. 61/093,001, filed on Aug. 29, 2008.

(51) Int. Cl. H01L 23/538; H01L 23/48; H01L 21/30; H01L 21/50

(52) U.S. Cl. 257/723; 257/773; 438/460; 438/107; 257/E23.011; 257/E23.169; 257/E21.211; 257/E21.499

(57) ABSTRACT

A sensor die in a sensor device includes a conformal dielectric coating over at least a die sidewall adjacent an interconnect edge and, in some devices, a conformal dielectric coating over at least part of the active area of the front side of the die. The sensor die can be connected to circuitry in a support by an electrically conductive material that is applicable in a flowable form, such as a curable electrically conductive polymer, which is applied onto or adjacent the dielectric coating on the die sidewall, and which is cured to complete connection between interconnect pads on the die and exposed sites on the support circuitry. In some devices, a coating over the active area of the sensor die provides mechanical and chemical protection for underlying structures in and on the die. In an image sensor device, for example, the coating over the image sensor array on the die is substantially optically transparent. Also, a package contains such a sensor die mounted on and electrically connected to a support; and assemblies include such a sensor die and additional die mounted on and electrically connected to opposite sides of a support. Also, methods are disclosed for making the sensor die, devices, packages, and assemblies.

### CROSS-REFERENCE TO RELATED APPLICATIONS

This application is a Continuation-in-Part of S. J. S. McElrea et al. U.S. application Ser. No. 12/550,012, filed Aug. 28, 2009, titled “Image sensor”, which claims priority from S. J. S. McElrea et al. U.S. Provisional Application No. 61/093,001, filed Aug. 29, 2008, titled “Image sensor”, both of which are hereby incorporated herein by reference.

### BACKGROUND

This invention relates to sensors, and, particularly, to sensors having sensing elements or devices situated in, or on, or at, or adjacent to, an active surface of a semiconductor circuit chip (the “sensor die”).

Sensors measure physical parameters (quantities or properties or phenomena) and convert them into signals that can be read or interpreted by a person or by an instrument. Such sensors include, for example: image sensors; surface contour sensors; fingerprint sensors; position, tilt, and/or motion sensors; force sensors, pressure sensors; and the like; and combinations of these.

Some sensors require substantially unencumbered access between the sensing element and the environment in which the particular physical parameter is to be measured. For example, fluid pressure sensors, that measure static pressure and/or changes in pressure of a liquid or gas, may require that the liquid or gas contact the sensing elements. And, for example, image sensors for example, require that the photons impinge upon the sensing elements. And, for example, chemical sensors require that the chemical of interest reach the sensors. And, for example, capacitance-based sensors employed in fingerprint recognition or fingerprint verification require that the subject's finger surface be brought into close proximity to the capacitance sensing elements. And, for example, contact-type profilometers require operative coupling between the contacting element and the surface to be measured. In many of such sensors the device in which the sensor is installed has an opening in the package or housing over the active side of the sensor die provide for the access to the environment.

In other sensors such access to the environment is not required. For example, sensors for measuring position or attitude, or movement or acceleration, can be fully enclosed by the package or housing.

Significant efforts have been directed to merging as much as possible of the required functionality for the various functions and features that might be merged into such devices in a single semiconductor (silicon) chip, but these efforts have not proven to be practical or cost effective.

Separate chips can be employed to carry out these various functions, and each die can be subjected to the best silicon processes for construction of particular circuits to carry out the functions. Where, for example, it is advantageous to include large amounts of memory storage in the product, it is often more cost effective to accomplish this in a system having multiple chips, including memory chips.

As the industry matures there is a drive to improve overall functionality as well as form factor and cost. Significant effort has been directed to thinning devices, reducing device footprints, and increasing density by stacking chips. To improve throughput and manufacturing reliability, there has been a tendency toward wafer level processing.

Factors intrinsic to sensing and processing, and to manufacture of devices intended to provide suitable sensing and processing, present particular technical challenges, in terms both of cost and of performance. Particular challenges may be presented by demands to decrease device footprint and thickness without compromising performance. And in sensors requiring access or near access to the environment providing a suitable opening in the device while protecting the active areas of the sensor presents additional challenges.

Packaging of sensors requiring access or near access to the environment presents particular challenges. Particularly, for example, the sensor must remain unobscured by other features of the package, and must be protected from damage during manufacturing operations and throughout the in-service life of the product into which it will be incorporated. As the electrical interconnection pads are at the sensor (active) side of the die, means must be provided to route the signals from the front surface of the die to the back for connection to underlying circuitry, such as a circuit board.

Image sensors present an example of a sensor requiring access to the environment. An image sensor is an electronic device that receives an optical image and converts it into an electronic signal. Conventional image sensors include, among others, charge-coupled devices (CCDs) and complementary metal oxide semiconductor (CMOS) devices. A variety of image sensor technologies have been proposed, presenting various (and sometimes competing) performance characteristics, and presenting particular technical challenges, particularly for example as relate to manufacturability. Performance improvements and lower cost of manufacture of CMOS image sensors have resulted in gains over conventional CCD image sensors, especially in consumer and hand-held applications such as cell phones, PDAs, digital music players, digital cameras, GPS devices, and the like.

In conventional image sensor cavity packages, for example, the image sensor die is mounted on a package substrate, and is electrically connected to the substrate using wire bonds. Wire bonds increase both the footprint and the thickness of the package, because the wire span and wire loop height must be accommodated. Additionally, to protect the sensing array and to permit optical access, a cover glass may be provided over the cavity, further increasing the thickness of the assembly.

In some approaches to improving footprint and package thickness, cover glass protection may be formed at the wafer level before die singulation. More recently, attention has been directed to so-called through silicon via (TSV) techniques to route electrical signals from the front (active) side of the sensor die to the backside. TSV is essentially a front-end approach requiring expensive equipment, and much process development remains before it can be considered ready for reliable, low cost manufacture. Capital equipment costs and lack of process maturity pose obstacles to widespread adoption of TSV.

Color filters may be provided on the surface of the sensor array, and micro-lenses may be incorporated on the surface of the chip for improving light sensitivity. These features are usually formed of polymers that cure at relatively low temperatures, and they can be deformed or damaged by elevated processing temperatures during packaging operations. To avoid damage to these parts of the image sensor, process temperatures during packaging of the image sensor chips must be kept low.

Capacitance-based fingerprint sensors present another example of a sensor requiring access to the environment, and such sensors present challenges particular to fingerprint sensing. A capacitance-based fingerprint sensor is an electronic device that captures a digital nonoptical image of the pattern of features (e.g., the ridges) in the fingerprint, and digitally processes it to construct a biometric profile or template. These sensors fall generally into two categories: active capacitance sensors and passive capacitance sensors. The fingerprint sensor die conventionally includes an array of capacitance sensors, which senses the difference in capacitance presented by the ridge patterns in the skin surface.

Fingerprint sensor packaging presents some particular challenges. As in the image sensor, the active area of the sensor die must remain unobscured by other features of the package, and must be protected from damage during manufacturing operations and throughout the in-service life of the product into which it will be incorporated. Typically the subject's finger is placed on the sensor die at an opening (e.g., a window) through the housing, and a protective plate or film is provided on the active surface of the sensor die. Accurate imaging requires close proximity of the skin surface and the active side of the capacitance sensor die.

As the electrical interconnection pads are at the capacitance sensor (active) side of the die, means must be provided to route the signals from the front surface of the die to the back for connection to underlying circuitry, such as a circuit board. In conventional fingerprint sensor packages, the capacitive sensor die is mounted on a package substrate, and is electrically connected to the substrate using wire bonds. The wire bonds are enclosed by a molding or encapsulation, which must be thick enough and must have a large enough footprint to accommodate the wire span and wire loop height. A window through the encapsulation or molding is provided for positioning the subject's finger, and the encapsulation or molding constitutes a frame that, because of its thickness, can interfere with positioning the finger in close proximity to the sensor die active surface.

### SUMMARY

In general the invention features a sensor. The sensor includes a sensor die, and a sensing element that is operatively coupled with or is part of the sensor die. The sensor die has a front side (the “active side”), a back side, and sidewalls; the active side has an active surface including a sensing area, and interconnect pads arranged adjacent at least one die edge (an “interconnectedge”); and the sensor die has a conformal dielectric coating over the interconnect edge and over an adjacent die sidewall (an “interconnect sidewall”). In some embodiments the active surface of the image sensor die further includes a peripheral circuitry area.

The sensor may be, for example, an image sensor; a surface contour sensor (profilometer); a fingerprint sensor; a position, tilt, and/or motion sensor; a force sensor, a fluid (liquid or gas) pressure sensor; a chemical sensor; and the like. The sensor may include two or more sensors of the same or of different types in any combination.

In one general aspect the invention features an image sensor, and the image sensor includes an image sensor die. The image sensor die has a front side (the “active side”), a back side, and sidewalls; the active side has an active surface including a sensor array area, and interconnect pads arranged adjacent at least one die edge (an “interconnectedge”); and the image sensor die has a conformal dielectric coating over the interconnectedge and over an adjacent die sidewall (an “interconnect sidewall”). In some embodiments the active surface of the image sensor die further includes a peripheral circuitry area.

In some embodiments the image sensor die further includes an optically transparent conformal dielectric coating over at the sensor array area, and in some embodiments additionally over the peripheral circuitry area.

In some embodiments the conformal dielectric coating may additionally cover the back side of the image sensor die. In some embodiments the image sensor die includes a die attach film at the back side. In some embodiments the image sensor die includes both a die attach film and a conformal dielectric coating at the back side and, in some such embodiments either the die attach film or the conformal dielectric coating may be applied onto the die back side surface.

In some embodiments the optically transparent conformal dielectric coating and the conformal dielectric coating over the die edges and die sidewalls are formed of the same material or of similar materials. Suitable materials at least for the optically transparent coating include organic polymers formed by vapor deposition, and a particularly useful conformal coating may be a polymer of p-xylene or a derivative thereof, such as a polyxylylene polymer, e.g., a parylene C or a parylene N, or a parylene A. In some embodiments the optically transparent conformal dielectric coating and the conformal dielectric coating over the die edges are formed as a continuous coating, and openings in the coating expose die pads for subsequent electrical connection to other circuitry.

In another general aspect the invention features a fingerprint sensor, and the fingerprint sensor includes a nonimaging sensor die, such as a capacitance sensor die. In some embodiments the sensor is configured as an active capacitance-type sensor; in some embodiments the sensor is configured as a passive capacitance-type sensor. The sensor die has a front side (the “active side”), a back side, and sidewalls; the active side has an active surface including a sensor array area, and interconnect pads arranged adjacent at least one die edge (an “interconnectedge”); and the sensor die has a conformal dielectric coating over the interconnect edge and over an adjacent die sidewall (an “interconnect sidewall”). In some embodiments the active surface of the image sensor die further includes a peripheral circuitry area.

In some embodiments the image sensor die further includes a conformal protective coating over at the sensor array area, and in some embodiments additionally over the peripheral circuitry area. In some embodiments the protective coating is a dielectric coating and in some embodiments the conformal protective coating may additionally cover the back side of the sensor die. In some embodiments the sensor die includes a die attach film at the back side. In some embodiments the sensor die includes both a die attach film and a conformal dielectric coating at the back side and, in some such embodiments either the die attach film or the conformal dielectric coating may be applied onto the die back side surface.

In some embodiments the conformal protective dielectric coating and the conformal dielectric coating over the die edges and die sidewalls are formed of the same material or of similar materials. Suitable materials include organic polymers formed by vapor deposition, and a particularly useful conformal coating may be a polymer of p-xylene or a derivative thereof, such as a polyxylylene polymer, e.g., a parylene C or a parylene N, or a parylene A. In some embodiments the conformal protective dielectric coating and the conformal dielectric coating over the die edges are formed as a continuous coating, and openings in the coating expose die pads for subsequent electrical connection to other circuitry.

In another general aspect the invention features a sensor including a sensor die, and a sensing element including a microelectromechanical system (also nanomicroelectromechanical system) (“MEMS”) apparatus operatively coupled with the sensor die. In some embodiments the sensor may employ capacitative or piezoelectric detection.

In some embodiments the MEMS apparatus may include a tip (a “stylus”) configured to contact a surface to be profiled. The sensor may be configured so that the surface can be moved in relation to the stylus, so that the stylus is displaced by the contour of the surface. Such a sensor may be employed as a contact profilometer.

In other embodiments the MEMS apparatus may include an inertial sensor, including parts responsive to acceleration, operatively coupled with the sensor die. Such a sensor may be employed as an accelerometer; and as such it may be capable of measuring velocity, position, orientation in two or more dimensions, vibration, or shock.

The sensor die has a front side (the “active side”), a back side, and sidewalls; the active side has an active surface including a sensor array area, and interconnect pads arranged adjacent at least one die edge (an “interconnectedge”); and the sensor die has a conformal dielectric coating over the interconnectedge and over an adjacent die sidewall (an “interconnect sidewall”). In some embodiments the active surface of the image sensor die further includes a peripheral circuitry area. In some embodiments the MEMS apparatus may be constructed at (on or in) the active surface of the sensor die.

In another general aspect the invention features a sensor package, including a sensor die mounted over a support. The sensor die has interconnect pads arranged adjacent at least one die edge (an “interconnectedge”), and has a conformal dielectric coating over the interconnectedge and over an adjacent die sidewall (a “interconnect sidewall”). The sensor die is electrically connected to interconnect sites at a first surface (the “interconnect surface”) of the support by traces of an electrically conductive material that is applied to or adjacent to the coated interconnectedge and sidewall; the trace makes contact with an exposed pad on the sensor die and with a site on the support. In some embodiments the sensor die additionally has a dielectric conformal coating over at least a sensor area of the active side, and in some embodiments additionally over a peripheral circuitry area of the active side.

In some embodiments two or more sensor die are mounted over and electrically connected to the support.

Suitable electrically conductive materials include materials that can be applied in a flowable form and then cured or allowed to cure to form the electrically conductive traces. Such materials include, for example, electrically conductive polymers, including electrically conductive particulates (e.g., conductive metal particles) contained in a curable organic polymer matrix (for example, conductive (e.g., filled) epoxies, or electrically conductive inks); and include, for example, electrically conductive particulates delivered in a liquid carrier. In particular embodiments the interconnect material is a conductive polymer such as a curable conductive polymer, or a conductive ink.

In some embodiments the support to which the sensor die is electrically connected is a circuit board, or a flex tape circuit, or a package substrate, or a leadframe, for example. Suitable package substrates include, for example, ball grid array (“BGA”) or land grid array (“LGA”) substrate, or a flex tape substrate.

In some such embodiments the sensor die may be mounted onto a surface of the package substrate (such as the interconnect surface) or the leadframe (such as a die mount surface, which may be a die paddle, for example); in other such embodiments an additional electrical device (such as an additional die) is interposed between the sensor die and the support to which the sensor die is electrically connected. Where the interposed electrical device includes circuitry (such as circuitry on an interposed additional die) the sensor die may additionally be electrically connected to circuitry on the interposed electrical device. Where the interposed electrical device is an additional die, the additional die may be, for example, a memory die, or a processor (such as a graphics processing unit), or a wireless communication chip, or a network access chip; or an additional sensor die.

In some embodiments the support to which the sensor die is electrically connected is an additional die; and in some such embodiments the interconnect sites on the additional die include die pads. That is, in such embodiments the interconnect traces make contact with an exposed pad on the sensor die and with an exposed pad on the additional die. In some such embodiments the additional die is mounted onto a package support such as a package substrate or leadframe; the additional die may be electrically connected to the support, and the sensor die may be electrically connected to interconnect sites on the die and additionally to interconnect sites on the support. The additional die may have any of a variety of functionalities, including for example processing (e.g., graphics processing) functionalities and memory functionalities; and the additional die may have a combination of functionalities.

In some embodiments having an additional electrical device interposed between the sensor die and the support to which the sensor die is electrically connected, the interconnect edge (or a portion thereof) of the sensor die may be set back from, or may be vertically aligned with, or may extend beyond, an edge of the interposed electrical device. In embodiments where the interconnectedge (or a portion thereof) extends beyond an edge of the interposed electrical device, the sensor die may be electrically connected to interconnect sites at the interconnect surface of the underlying support by pedestals of electrically conductive material at the sites on the support and traces of an electrically conductive material that is applied to or adjacent to the coated interconnectedge and sidewall and that make contact with the pedestals.

In some embodiments the support to which the sensor die is electrically connected is a stack of additional die; and in some such embodiments the interconnect sites on the additional die include die pads. That is, in such embodiments the interconnect traces make contact with an exposed pad on the sensor die and with an exposed pad on at least one of the additional die. In some embodiments two or more of the additional die may be interconnected in the stack. In some such embodiments the stack of additional die is mounted onto a package support such as a package substrate or leadframe; the stack of additional die may be electrically connected to the support, and the sensor die may be electrically connected to interconnect sites on at least one of the additional die and additionally to interconnect sites on the support. The additional die in the stack may have any of a variety of functionalities, including for example processing (e.g., graphics processing) functionalities and memory functionalities; the die in the stack may have the same functionalities, or, various die in the stack may have different functionalities; one or more of the additional die in the stack may have a combination of functionalities. In particular embodiments, for example, a memory die (or a stack of memory die) may be stacked on a processor die such as a graphics processor unit (“GPU”), and these die may be interposed between the sensor die and the support.

In some embodiments an additional electrical device is mounted on and electrically connected to interconnect sites at a second surface of the support. The second surface of the support may be an area on the same side of the support as the interconnect surface; or the second surface may be an area on the opposite side of the support. The additional electrical device mounted on the second surface of the support may include, for example, an additional die or stack of additional die or a semiconductor package.

In some embodiments an additional electrical device is interposed between the sensor die and a first surface of the support, and a further additional electrical device is mounted on and electrically connected to interconnect sites at a second surface of the support.

In some such embodiments the support comprises a package substrate, such as a ball grid array (“BGA”) or land grid array (“LGA”) substrate, or a flex tape substrate.

In another general aspect the invention features a sensor assembly, including a sensor die mounted on and electrically connected to a first surface of a support as described above, and additionally including at least one die having another functionality mounted on and connected to circuitry at the opposite side of the support. In particular embodiments of such an assembly, for example, the sensor die is mounted on and electrically connected to sites on a first surface of a package substrate, and a stack of electrically interconnected memory die is mounted on and electrically connected to sites at the opposite side of the substrate.

In another general aspect the invention features a wafer level or die array level method for making a sensor package, including providing a wafer having sensor circuitry formed on an active side thereof, cutting the wafer to form die edges and die sidewalls (including interconnectedges along which die pads are arranged and interconnect sidewalls adjacent the interconnectedges), and depositing a conformal dielectric coating over the front side of the cut wafer, including the interconnectedges and die sidewalls. In particular embodiments the conformal coating is a parylene, formed by vapor deposition.

In some embodiments the wafer level method or die array level method includes thinning the wafer by removal of material from the wafer backside (“backgrinding”). In some such embodiments the wafer is cut at least in part after backgrinding; in some embodiments the wafer is cut at least in part before backgrinding; in some embodiments the wafer is cut by two or more cutting procedures, and the backgrind is carried out between the cutting procedures.

In another general aspect the invention features a method for making a sensor package, including providing a die having a front side and a back side and sensor circuitry formed on the active side, the die having die sidewalls defining die edges (including interconnect edges along which die pads are arranged and interconnect sidewalls adjacent the interconnect edges); applying a conformal dielectric coating over at least the interconnect edges and the interconnect sidewalls; providing a support having connection sites at a first surface thereof; mounting the die over the first surface and electrically connecting the die to circuitry in the support, by applying traces of an electrically conductive material to or adjacent to the coated interconnectedge and sidewall in contact with an exposed pad on the die and with a connection site on the support.

In some embodiments the method includes applying a conformal dielectric coating over the front side of the sensor die; in some embodiments the method includes applying a conformal dielectric coating over the back side of the die; and in some embodiments the method includes applying a conformal dielectric coating over the front side and the back side of the die. In particular embodiments the method includes applying a conformal dielectric coating over all sides of the sensor die. In some such embodiments applying a conformal dielectric coating over the front side of the die, and/or over the back side of the die, can be carried out concurrently with applying conformal coating over the interconnect edges and the interconnect sidewalls. In some embodiments applying the conformal dielectric coating further includes selectively removing areas of the coating to expose features (such as interconnect pads). In particular embodiments applying the conformal coating includes coating die surfaces with a parylene, and selectively removing areas of the coating includes directing laser energy at the areas.

In some embodiments mounting the sensor die over the first surface of the support includes mounting an additional electrical device on the first surface of the support, and affixing the sensor die on a surface of the additional electrical device. In some embodiments affixing the sensor die includes applying a die attach film or a die attach adhesive to the back side of the sensor die or to the surface to which the die is mounted. In some embodiments, where the die has a suitable conformal dielectric coating (such as a parylene film) over the back side, it may be unnecessary to employ a die attach film or die attach adhesive between the back side of the sensor die and the surface to which it is affixed, as the conformal dielectric coating may serve to affix the die to the support surface.

In any of the above described sensor packages, sensor assemblies, and methods for making them, the sensor itself may be, for example, an image sensor; a surface contour sensor (profilometer); a fingerprint sensor; a position, tilt, and/or motion sensor; a force sensor, a fluid (liquid or gas) pressure sensor; and the like. The sensor itself may include two or more sensors of the same or of different types in any combination.

the sensor itself may be, for example, an image sensor; a surface contour sensor (profilometer); a fingerprint sensor; a position, tilt, and/or motion sensor; a force sensor, a fluid (liquid or gas) pressure sensor; a chemical sensor; and the like; or any combination of two or more of these.

The die, packages, and assemblies according to the invention can be used in computers, telecommunications equipment, and consumer and industrial electronics devices, by installation in or on the devices and electrical connection to circuitry in the devices.

### BRIEF DESCRIPTION OF THE DRAWINGS

FIG. 1 is a diagrammatic sketch in a transverse sectional view showing a conventional optical sensor cavity package, having a glass cover lens.

FIG. 2 is a diagrammatic sketch in a transverse sectional view showing a conventional optical sensor cavity package, having microlenses over the sensor array and a protective glass cover.

FIG. 3 is a diagrammatic sketch in transverse sectional view showing an embodiment of an optical sensor package of the invention.

FIG. 4 is a diagrammatic sketch in transverse sectional view showing a portion of an embodiment of an optical sensor package as in FIG. 3 of the invention, enlarged.

FIG. 5A is a diagrammatic sketch in a transverse sectional view showing a BGA optical sensor package according to an embodiment of the invention.

FIG. 5B is a diagrammatic sketch in an elevational view showing a BGA optical sensor package as in FIG. 5A.

FIG. 6 is a diagrammatic sketch in an elevational view showing an optical sensor package assembly according to an embodiment of the invention, having an optical sensor die mounted onto one surface of a support, and a stack of memory die mounted on the opposite surface of the support.

FIG. 7 is a diagrammatic sketch in an elevational view showing an optical sensor package assembly according to another embodiment of the invention, having an optical sensor die mounted over one surface of a support and electrically connected to the support, and an additional electrical device interposed between the optical sensor die and the support surface.

FIG. 8 is a diagrammatic sketch in an elevational view showing an optical sensor package assembly according to another embodiment of the invention, having an optical sensor die mounted onto and electrically connected to an additional die.

FIG. 9 is a diagrammatic sketch in an elevational view showing an optical sensor package assembly according to another embodiment of the invention, having an optical sensor die mounted onto and electrically connected to an additional electrical device, in which the additional device is mounted onto and electrically connected to an additional support.

FIG. 10 is a diagrammatic sketch in an elevational view showing an optical sensor package assembly according to another embodiment of the invention, having an optical sensor die mounted onto and electrically connected to an upper one of a stack of memory die, in which the memory die stack is mounted onto and electrically connected to an additional support.

FIG. 11 is a diagrammatic sketch in an elevational view showing an optical sensor package assembly according to another embodiment of the invention, having an optical sensor die mounted over one surface of a support and electrically connected to the support, and an additional electrical device interposed between the optical sensor die and the support surface.

FIG. 12A is a diagrammatic sketch in a sectional view showing, for reference, an embodiment of a generalized sensor package of the invention.

FIG. 12B is a diagrammatic sketch in a sectional view showing a portion of an embodiment of a generalized sensor package of the invention as in FIG. 12A, enlarged.

FIGS. 13A, 13B are diagrammatic sketches in sectional view showing fingerprint sensor packages according to further embodiments of the invention.

FIG. 14 is a diagrammatic sketch in a sectional view showing a profilometer sensor package according to a further embodiment of the invention.

### DETAILED DESCRIPTION

The invention will now be described in further detail by reference to the drawings, which illustrate alternative embodiments of the invention. The drawings are diagrammatic, showing features of the invention and their relation to other features and structures, and are not made to scale. For improved clarity of presentation, in the FIGs. illustrating embodiments of the invention, elements corresponding to elements shown in other drawings are not all particularly renumbered, although they are all readily identifiable in all the FIGs. Also for clarity of presentation certain features are not shown in the FIGs., where not necessary for an understanding of the invention.

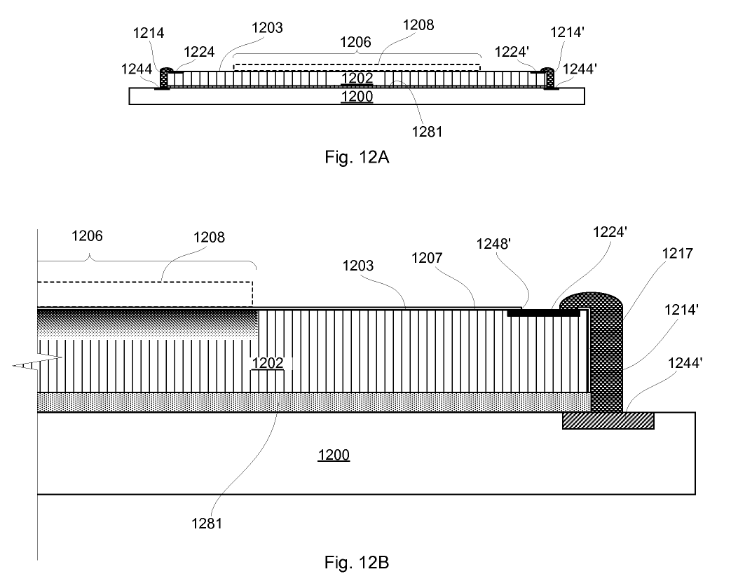

Reference is made first to FIG. 12, showing in a sectional view an embodiment of a generalized sensor package, which includes a sensor die and a sensing element that is operatively coupled with or is part of the sensor die. A sensor die 1202 is mounted on the sensor die mount side of a support 1200 such as a package substrate using, in this example, a die attach film 1281. The die 1202 is mounted with the active (sensor) front side 1203 facing away from the support 1200. Circuitry on the active side of the die includes a sensor area 1206, and interconnect die pads 1224, 1224′. The sensing element that is operatively coupled with or is part of the sensor die 1202 is indicated generally at 1208.

A layer of electrically conductive material (a metal or metallization) on the substrate is patterned to form conductive traces, including bond pads 1244, 1244′. According to the invention, the sensor die 1202 is electrically connected to the support by interconnect traces 1214, 1214′ of electrically conductive material that contacts and provides electrical continuity between interconnect die pads (e.g., pad 1224′) and corresponding sites in the support (e.g., bond pad 1244′). Suitable electrically conductive materials include materials that can be applied in a flowable form and then cured or allowed to cure to form the electrically conductive traces. Such materials include, for example, electrically conductive polymers, including electrically conductive particulates (e.g., conductive metal particles) contained in a curable organic polymer matrix (for example, conductive (e.g., filled) epoxies, or electrically conductive inks); and include, for example, electrically conductive particulates delivered in a liquid carrier. The material may be applied by dispensing, or printing, or spraying, for example. Examples of suitable interconnect materials, and techniques for applying them, are described for example in T. Caskey et al. U.S. patent application Ser. No. 12/124,097, titled “Electrical interconnect formed by pulsed dispense”, which was filed May 20, 2008, which is hereby incorporated herein by reference. Conductive inks may be applied by aerosol spray, for example, and may following application be sintered or cured, according to the constitution of the particular ink. Particles in a carrier may be dispensed or applied by aerosol spray, for example, and may following application be sintered to form the electrically conductive traces. Aerosol spray application is described, for example, in J. S. Leal et al. U.S. application Ser. No. 12/634,598, titled “Semiconductor die interconnect formed by aerosol application of electrically conductive material”, which was filed Dec. 9, 2009, which is incorporated herein by reference.

The interconnection in an example as in FIG. 12A is more clearly seen in an enlarged view in FIG. 12B. The die sidewall and die edge adjacent the die pads are in this example covered by an electrically insulative conformal coating 1217. The electrically conductive material is applied in a flowable form onto or adjacent the electrically insulative conformal coating and is then cured.

Additionally, as illustrated in FIG. 12B, a conformal coating 1207 may optionally cover at least part of the active side 1203 of the die 1202; the part covered may include the sensor area 1266 or may include at least an area of any peripheral control circuitry on the die, or may include both the sensor area and an area of the peripheral circuitry. Openings (e.g., opening 1248′ in the coating expose portions of selected die pads (e.g., pad 1224′) for electrical access to the interconnect 1214′.

As noted above, the sensor may in various embodiments be, for example, an image sensor; a surface contour sensor (profilometer); a fingerprint sensor; a position, tilt, and/or motion sensor; a force sensor, a fluid (liquid or gas) pressure sensor; a chemical sensor; and the like; or any sensors in combination. In these various embodiments the sensing element and sensing die are selected and configured accordingly.

A protective coating over at least part of the front side of the die may be desirable. Where for the particular sensor type the physical parameter to be sensed must contact the surface of the active side of the die, the die surface (or at least the sensing area of the die surface) may be left uncovered. For example, a chemical sensor may require that a carrier or medium (e.g., liquid or gas) containing the chemical to be detected make direct contact with the die surface or with a reagent attached to the die surface. Where the physical sensor to be sensed need not directly contact the surface of the active side of the die, the surface (or an area of the surface) may be covered with a protective coating selected not to interfere with the sensing function. For example, a protective coating over the active side of an optical sensor should optically transmit at least the wavelengths to be detected; and for an image sensor it should have optical characteristics selected to transmit the image. And, for example, a protective coating over the active side of a capacitance-type fingerprint sensor should not interfere with detection of capacitance by the underlying capacitance detection circuitry.

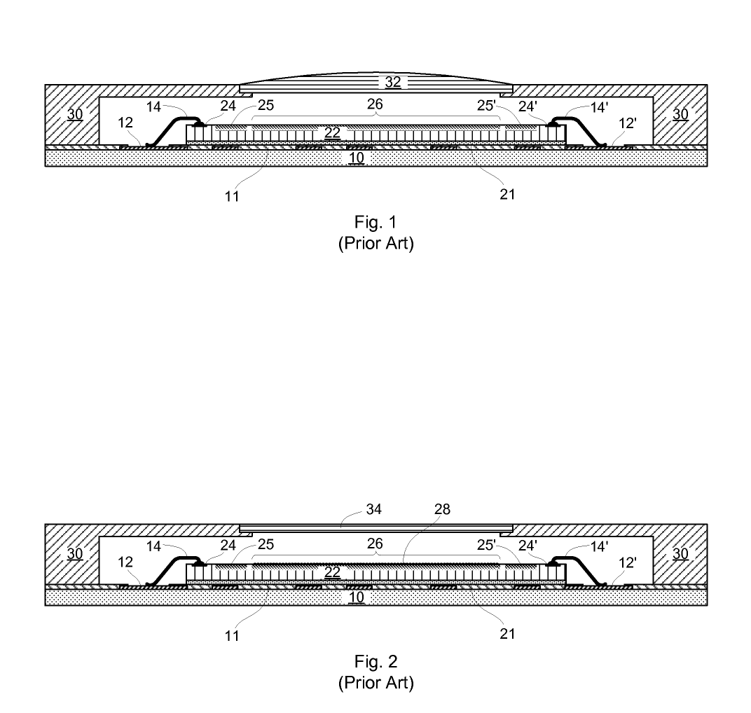

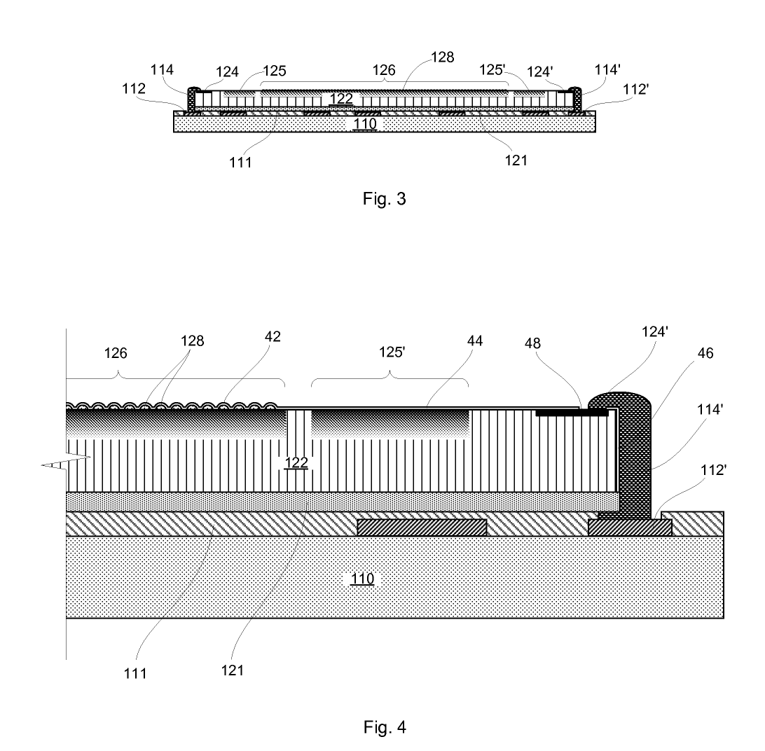

For illustration the following FIG. 1 et seq. are directed to image sensors, with FIGS. 1 and 2 illustrating the prior art; and FIG. 3 et seq. showing examples of embodiments of the invention.

Turning now to FIG. 1, there is shown in a sectional view an example of a conventional optical sensor cavity package. A CMOS optical sensor die 22 is mounted on the sensor die mount side of a package substrate 10 using a die attach film 21. The die 22 is mounted with the active (sensor) front side facing away from the substrate 10. Circuitry on the active side of the die includes a photosensor array 26, and access and decoding circuitry 25, 25′, and interconnect die pads 24, 24′. A layer of electrically conductive material (a metal or metallization) on the substrate is patterned to form conductive traces, including bond pads 12, 12′. A dielectric layer 11 such as a solder mask over the conductive traces has openings exposing the bond pads. The optical sensor die 22 is electrically connected to the substrate by bond wires 14, 14′, which connect die pads (e.g., pad 24′) to corresponding bond pads (e.g., bond pad 12′). A cover support 30 mounted on the substrate 10 supports a glass cover 32 over the sensor area of the die. In this example, the glass cover is formed as a lens. Light enters the assembly through the lens 32, which directs an image toward the sensor array 26.

FIG. 2 shows in a sectional view another example of a conventional optical sensor cavity package. As in the example of FIG. 1, here a CMOS optical sensor die 22 is mounted on the sensor die mount side of a package substrate 10 using a die attach film 21. The die 22 is mounted with the active (sensor) front side facing away from the substrate 10. Circuitry on the active side of the die includes a photosensor array 26, and access and decoding circuitry 25, 25′, and interconnect die pads 24, 24′. An array 28 of microlenses is formed over the sensor array 26. A layer of electrically conductive material (a metal or metallization) on the substrate is patterned to form conductive traces, including bond pads 12, 12′. A dielectric layer 11 such as a solder mask over the conductive traces has openings exposing the bond pads. The optical sensor die 22 is electrically connected to the substrate by bond wires 14, 14′, which connect die pads (e.g., pad 24′) to corresponding bond pads (e.g., bond pad 12′). A cover support 30 mounted on the substrate 10 supports a glass cover 32 over the sensor area of the die. Light passes through the cover 34 and onto the microlenses 28 on the sensor array 26.

As FIGS. 1 and 2 illustrate, in these conventional packages the wire bonds and the glass cover support contribute to an overall package footprint and thickness that is significantly greater than the footprint of the optical sensor die.

FIG. 3 shows in a sectional view an example of an image sensor package according to an embodiment of the invention, in which an optical sensor die is mounted onto and is electrically connected to a support. In this example an optical sensor die such as a CMOS optical sensor die 122 is mounted on the sensor die mount side of a package substrate 110 using a die attach film 121. The die 122 is mounted with the active (sensor) front side facing away from the substrate 110. Circuitry on the active side of the die includes a sensor array 126, and access and decoding circuitry 125, 125′. In this example an array of microlenses 128 is formed on the sensor array 126. A layer of electrically conductive material (a metal or metallization) on the substrate is patterned to form conductive traces, including bond pads 112, 112′. A dielectric layer 111 such as a solder mask over the conductive traces has openings exposing the bond pads.

The sensor array 126 may include an array of any of a variety of photosensors, including any of a variety of solid state imaging devices, such as, for example, photodiodes, phototransistors.

According to the invention, the optical sensor die 122 is electrically connected to the support by interconnect traces 114, 114′ of electrically conductive material that contacts and provides electrical continuity between interconnect die pads (e.g., pad 124′) and corresponding sites in the support (e.g., bond pad 112′). Suitable electrically conductive materials include materials that can be applied in a flowable form and then cured or allowed to cure to form the electrically conductive traces. Such materials include, for example, electrically conductive polymers, including electrically conductive particulates (e.g., conductive metal particles) contained in a curable organic polymer matrix (for example, conductive (e.g., filled) epoxies, or electrically conductive inks); and include, for example, electrically conductive particulates delivered in a liquid carrier. The material may be applied by dispensing, or printing, or spraying, for example. Examples of suitable interconnect materials, and techniques for applying them, are described for example in T. Caskey et al. U.S. patent application Ser. No. 12/124,097, titled “Electrical interconnect formed by pulsed dispense”, which was filed May 20, 2008, and which is incorporated herein by reference. Conductive inks may be applied by aerosol spray, for example, and may following application be sintered or cured, according to the constitution of the particular ink. Particles in a carrier may be dispensed or applied by aerosol spray, for example, and may following application be sintered to form the electrically conductive traces.

The interconnection in an example as in FIG. 3 is more clearly seen in an enlarged view in FIG. 4. The die sidewall and die edge adjacent the die pads are in this example covered by an electrically insulative conformal coating 44. The electrically conductive material is applied in a flowable form onto or adjacent the electrically insulative conformal coating and is then cured.

In an example as illustrated in FIGS. 3 and 4, an electrically insulative optically clear conformal coating 42 additionally covers the active side of the die 122, including the sensor array 126 and the peripheral circuitry 125, 125′. Openings 48 in the coating expose portions of selected die pads (e.g., pad 124′) for electrical access to the interconnect 114′.

The conformal coating transmits light to the optical sensor. Accordingly, the conformal coating may be substantially optically clear at least to wavelengths at which the optical sensor is intended to operate. Where for example the optical sensor die is intended to operate at wavelengths over the entire visible spectrum, the conformal coating transmits wavelengths at least in the visible region. The optical sensor may be intended to operate in UV, deep UV, or IR; and the conformal coating in such instances transmits wavelengths at least in the corresponding parts of the spectrum. The conformal coating also provides mechanical and chemical protection to the underlying structures. A preferred coating material does not require temperature elevation, does not shrink during coating formation, and protects the underlying surfaces during wafer processing.

Useful conformal coatings include organic polymers formed by vapor deposition, and a particularly useful conformal coating may be a polymer of p-xylene or a derivative thereof, such as a polyxylylene polymer, e.g., a parylene C or a parylene N, or a parylene A. Openings in the coating may be formed, where required, by selective laser ablation, for example.

The conformal parylene coating is formed by vapor deposition, and the coatings can be formed at the wafer level or at the die array level of processing. Stages in an example of a wafer process are as follows, for example. The wafer is provided, with image sensor (e.g., CMOS sensor) circuitry formed thereon.

In a cut-before-thinning procedure, the wafer is cut at the active side, for example by sawing using a dicing saw, to a depth in the wafer material slightly greater than the final die thickness, so that the die sidewalls are formed, but the die are not fully singulated. The cut wafers are then placed in a parylene deposition chamber, and deposition is carried out to form a thin coating on the exposed surfaces, that is, on the front side of the die and on the exposed die sidewalls.

The coating is formed to a thickness sufficient to provide a continuous coating (free of pinholes), and sufficient to provide electrical insulation with a dielectric strength that meets or exceeds the requirements of the underlying circuitry. Parylene coating thicknesses in a range about 1 um to about 5 um may be suitable, for example. After the coating is complete, the wafer is removed from the parylene chamber and a laser ablation system is used to remove the coating from the interconnect die pads on the front surface of the die. As may be appreciated, the laser must be operated at a wavelength at which there is appreciable energy absorption in the coating layer, considering that parylene is substantially transparent in the visible range between 300 and 800 nanometers. Optionally, the removal of coating material from the pads may be carried out at a later stage, at any time up to the time electrical connection of the die is to be carried out.

The wafer is then thinned to a specified die thickness (typically, for example, 50 um or less) by, for example, backgrinding, Because the wafer had previously been cut to a depth exceeding the die thickness, the backgrinding results in singulation of the die.

In a cut-after-thinning procedure, the wafer as provided is thinned, for example by backgrinding, to a desired die thickness; and then the wafer is cut through either from the wafer front side or from the wafer backside to yield singulated die in a die array. Then the die array is supported with the active side and die edges and sidewalls exposed, and treated as described above to form the conformal coating over the exposed surfaces. Then laser ablation is used to expose interconnect pads on the die.

A hybrid cut-and-thin die separation process may be used, particularly where interconnect die pads are arranged in the die margin along one or two die edges. Hybrid cut-and-thin processes are described in R. Co et al. U.S. application Ser. No. 12/323,288, titled “Semiconductor die separation method”, which was filed Nov. 25, 2008, and which is incorporated herein by reference. Briefly, the wafer is cut in two stages. The first cutting procedure may be carried out prior to wafer thinning to the desired die thickness, or wafer thinning may be carried out prior to the first cutting procedure. In the first cutting procedure the wafer is cut from the front side along streets fronting the interconnectedges to a depth less than the die thickness, to form interconnect die edges and at least partial interconnect sidewalls; and the wafer is cut along the other streets to a depth at least about the die thickness. Thereafter the wafer array is treated as described above to form the conformal coating over the front side and die edges and interconnect sidewalls. Thereafter the wafer is cut in a second cutting procedure along the streets fronting the interconnect sidewalls to singulate the die and complete the die sidewalls.

A die attach film can optionally be applied to the backside of the thinned wafer (in a cut after thinning procedure, or in a hybrid cut-and-thin procedure) or to the back sides of the singulated die while they are in a die array, and then a pick-and-place operation is employed to affix the singulated die to an appropriate support such as a package substrate, or a circuit board, or a flex circuit, or another die, for example. Where a suitable conformal dielectric coating (such as a parylene film) is formed over the back side, it may be unnecessary to employ a die attach film or die attach adhesive between the back side of the image sensor die and the surface to which it is affixed, as the conformal dielectric coating may serve to affix the die to the support surface. Where a die attach film is employed, it may be advantageous to apply the film to the thinned wafer backside or to the die back sides at the die array level; and, particularly, it may be advantageous in a cut after thinning procedure or in a hybrid cut-and-thin procedure to apply the die attach film prior to completing wafer cutting, to help avoid die shift or die tilt during subsequent processing steps.

In other embodiments the conformal coating may be removed from or may be omitted from the area of the active side of the die overlying the image array area. The advantages of protecting the image array surface during subsequent processing are lost in such embodiments, however.

Suitable electrically conductive materials for the electrical interconnect are applied in a flowable form, subsequently cured or permitted to harden. The interconnect material may be an electrically conductive polymer; or a conductive ink. The interconnect material may be a curable conductive polymer, for example, such as a curable epoxy; and the interconnect process may include forming traces of the uncured material in a prescribed pattern and thereafter curing the polymer to secure the electrical contacts with the lead ends and the interconnect sites and the mechanical integrity of the traces between them. The interconnect material may be applied using an application tool such as, for example, a syringe or a nozzle or a needle; more usually the tool is a deposition head, configured to automatically (for example, robotically) and accurately deposit the material. The material is applied by the tool in a deposition direction generally toward the lead ends at the sidewall surface, and the tool is moved over the presented die sidewall of die stack face in a work direction. The material may be extruded from the tool in a continuous flow, or, the material may exit the tool dropwise. In some embodiments the material exits the tool as a jet of droplets, and is deposited as dots which coalesce upon contact, or following contact, with the electrically insulated die sidewall surface. In some embodiments the material is applied in an aerosol spray. In some embodiments the deposition direction is generally perpendicular to the die sidewall surface, and in other embodiments the deposition direction is at an angle off perpendicular to the stack face surface. The tool may be moved in a generally linear work direction, or in a zig-zag work direction, depending upon the location on the die and on the substrate of the various pads to be connected.

Prior to application of the interconnect material the surface of the die pad and/or the connection site on the support may optionally be provided with an element (or elements) which, under the cure conditions, can together with an element (or elements) in the interconnect material, form an intermetallic at the interface of the interconnect material and the pad or site surface.

Optionally, a plurality of deposition tools may be held in a ganged assembly or array of tools, and operated to deposit one or more traces of material in a single pass. Alternatively, the material may be deposited by pin transfer or pad transfer, employing a pin or pad or ganged assembly or array of pins or pads.

The application of the interconnect material may be automated; that is, the movement of the tool or the ganged assembly or array of tools, and the deposition of material, may be controlled robotically, programmed as appropriate by the operator. Alternatively the interconnect material may be applied by printing, for example using a print head (which may have a suitable array of nozzles), or for example by screen printing or using a mask or stencil.

As FIG. 3 illustrates, only a very narrow margin of support (e.g., substrate) is necessary surrounding the die, because the interconnections are made on or adjacent the insulated die sidewall. Accordingly, the footprint of the optical sensor package can be made only slightly larger than the die footprint. Also, as FIG. 3 illustrates, the overall package height can be made only slightly greater than the sum of the thicknesses of the die and the substrate, plus the thickness of a die attach material.

The illustrated examples have one image sensor die mounted over the support. In other embodiments two or more image sensor die are mounted over and electrically connected to the support. In such embodiments the various die may be operationally the same, providing redundancy or additive image-forming capability. Or, for example, the various die may be operational at different parts of the spectrum. For example, three die operating in the visible region may be sensitive respectively to red, green, and blue wavelengths; and, in such embodiments, an additional fourth die may be sensitive at wavelengths generally over the visible region. Or, for example, one or more die may be sensitive to a part or parts of the visible region, and one or more additional die may be sensitive to wavelengths outside the visible region, such as UV, deep UV, and/or IR, for example.

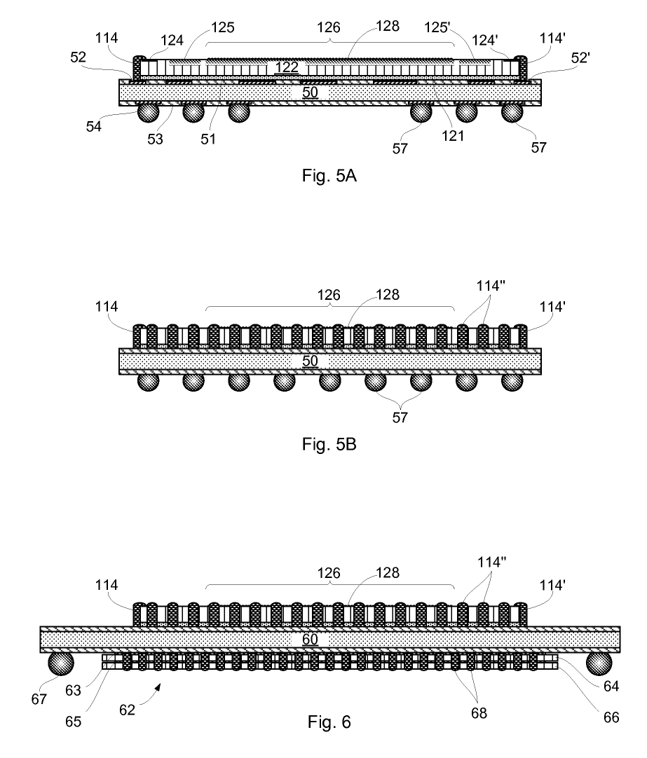

The support shown in the examples of FIGS. 3 and 4 are package substrates; that is they include one or more patterned electrically conductive layers (such as metal films or metallizations) and one or more dielectric layers, with bond sites exposed at one surface for electrical connection to the optical sensor die. Other supports are contemplated. Other supports include, for example, package substrates having electrical connection sites on both a surface over or upon which the optical sensor die is mounted and an opposite surface, such as ball grid array (“BGA”) or land grid array (“LGA”) substrates; electrical connection sites on the opposite surface may serve for z-interconnection the package assembly to underlying circuitry in a device in which the optical sensor is deployed (as illustrated for example in FIGS. 5A, 5B, described below); or for electrical connection of other electrical features or both for z-interconnection and for electrical connection of other electrical features (as illustrated for example in FIG. 6, described below). A variety of supports are contemplated, including, for example, additional die; leadframes; printed circuit boards; flex tape substrates; glass plates.

FIGS. 5A and 5B show an example of an embodiment of an optical sensor package in which the die support is a ball grid array (BGA) substrate. The optical sensor die in this example is similar to that illustrated in FIGS. 3 and 4. The BGA substrate in this example includes at least two patterned electrically conductive metal (or metallization) layers, separated by a dielectric layer or layers. One conductive layer is at the die mount side, and is covered by a solder mask 51 having openings exposing bond pads (e.g., 52, 52′) generally as in the support shown in FIGS. 3 and 4. In these examples the optical sensor die 122 is electrically connected to the substrate 50 by interconnect traces 114, 114′ and 114″ of electrically conductive material that contacts and provides electrical continuity between interconnect die pads (e.g., 124, 124′ in FIG. 5A; the pads are not shown in FIG. 5B) to corresponding bond pads in the substrate (e.g., 52, 52′ in FIG. 5A; the pads are not shown in FIG. 5B). A second conductive layer is at the side of the substrate opposite the die mount side, and is covered by a solder mask 53 having openings exposing solder ball lands (54 in FIG. 5A; the lands are not shown in FIG. 5B) for reflow attachment of solder balls 54, for interconnection of the package to underlying circuitry in the device in which the sensor is deployed. The patterned conductive layers are connected by vias through the dielectric layer of the support. The underlying circuitry may be on a printed circuit board, for example, to which other die (or other packages) having other functionalities are mounted and electrically connected.

Additional electrical devices may be electrically connected to the side of the support opposite the side over which the optical sensor die is mounted. Any of a variety of electrical devices may be deployed in such embodiments; including, for example, a semiconductor die; a stack of semiconductor die; a semiconductor die package; one or more passive or active electrical features; a carrier having electrical circuitry; a carrier having electrically connected passive features or active features. By way of example, FIG. 6 shows in an elevational view an example of an embodiment of a multi-die assembly according to the invention, in which an image sensor die is mounted onto and electrically connected at a sensor die attach side to a support 60 (such as a package substrate, for example) in a manner as described with reference to FIGS. 5A, 5B; and a stack 62 of die having another functionality is mounted on and electrically connected at the side of the support opposite the sensor die attach side. The support has at least two patterned electrically conductive layers, one at the sensor die mount side and the other at the opposite side, separated by a dielectric layer or layers, and connected by vias through the dielectric layer, as described with reference to FIG. 5A. In this example the electrically conductive layer at the opposite side has exposed solder ball pads arranged for attachment of peripheral solder balls (e.g., 67) by which the package can be connected to underlying circuitry (for example in a printed circuit board) in the device in which the package is deployed. The electrically conductive layer at the opposite side has exposed interconnect pads arranged for interconnection of the die in the stack 62. In the example shown, a first die 64 in the stack 62 is mounted onto the support 60 surface using a die attach adhesive (such as a die attach film or a die attach epoxy, for example); and a second die 66 in the stack 62 is mounted onto the first die 64 using a die attach adhesive (such as a die attach film or a die attach epoxy, for example). Also, in the example shown the first and second die in the stack 62 are electrically interconnected die-to-die, and connected to interconnect pads (not shown in the FIG.) on the circuitry on the support, using traces 68 of an interconnect material that is applied in a flowable form, in a manner similar to that described above for connection of the image sensor die to the sensor die mount side of the support. Suitable connections alternatively include wire-bonding, tab-interconnect, flip-chip interconnect, and the like. The die in the stack 62 may have the same functionality (or example, they may be memory die), or they may have different functionalities; and the die may have the same or different dimensions. The stack 62 may include more than two die; and, a single die may be mounted on the substrate in place of the stack 62.

In FIGS. 5B and 6 the optical sensor die are shown as having electrical connections to the support along three die sidewalls (interconnect traces 114, 114′ and 114″). In some examples the optical sensor die may—depending upon its pad layout—have die pads (and electrical connections in the package) along all four die sidewalls (including the one not visible in these FIGs.); or along just two die sidewalls; or along just one die sidewall.

FIG. 8 illustrates an example of an optical sensor assembly in which an optical sensor die 122 is mounted onto and is electrically connected to, another die 80. That is, in this example a die constitutes the support. The image sensor die 122 in this example is affixed using a die attach film onto a surface 81 of the die 80. Electrical connection is made by way of conductive traces 74, 74′ contacting die pads 724, 724′ on the image sensor die and contacting pads 844, 844′ on the die 180.

In other embodiments the optical sensor die is mounted over and electrically connected to the support, and an additional electrical device (or a device stack having one or more additional electrical devices) is interposed between the optical sensor die and the support. The optical sensor die may optionally be electrically connected to the interposed electrical device (or to one or more of the additional devices in the stack); the interposed additional device (or one or more of the devices) may optionally be electrically connected to the support; and, where a stack of devices is interposed between the optical sensor die and the support, the additional devices may optionally be connected to each other in the stack. Any of a variety of electrical devices may be deployed in such embodiments, including, for example, a semiconductor die; a stack of semiconductor die; a semiconductor die package; one or more passive or active electrical features; a carrier having electrical circuitry; a carrier having electrically connected passive features or active features. Some illustrative examples follow.

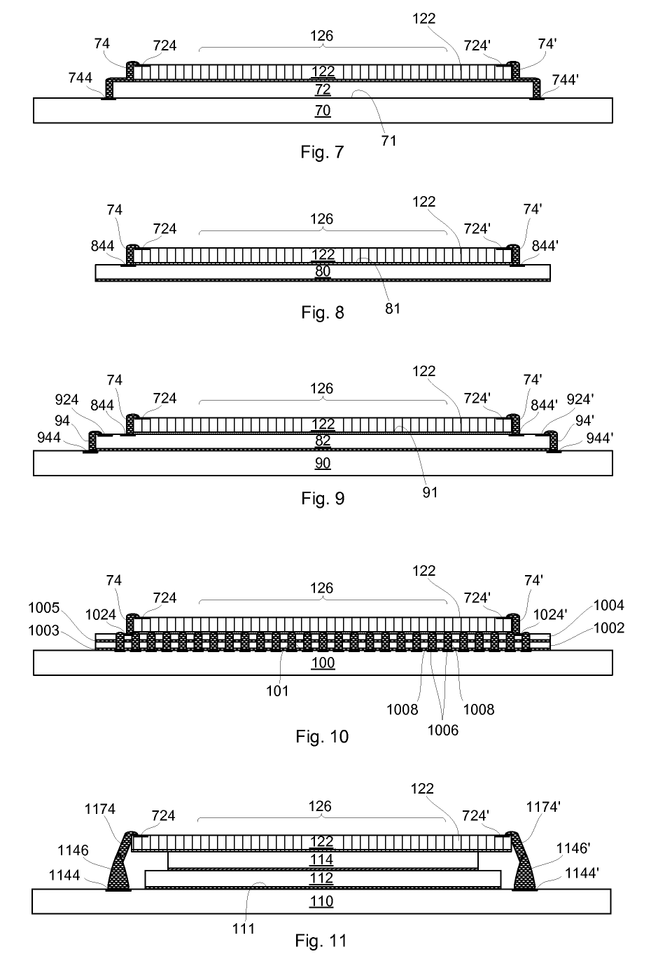

FIG. 7 illustrates an example of an optical sensor assembly in which an optical sensor die 122 is mounted over (not directly onto) a support 70, with an additional electrical device 72 interposed between the optical sensor die and the support surface. In this example the optical sensor die 122 is not shown as being electrically connected directly to the additional electrical device 72; and the additional device 72 is not shown as being electrically connected directly to the support 70. As may be appreciated, the additional device may optionally be electrically connected to the support 70 by any of a variety of second-level interconnect configurations (not represented in FIG. 7), including electrically conductive traces formed of conductive materials applied in a flowable form and then cured or allowed to cure; and including wire-bonding, tab-interconnect, or flip-chip interconnect, and the like.

FIG. 9 illustrates an example of an optical sensor assembly in which an optical sensor die 122 is mounted over (not directly onto) a support 90, with an additional electrical device 82 interposed between the optical sensor die and the substrate surface. In this example, the optical sensor die 122 is electrically connected to the interposed electrical device 82 by way of conductive traces 74, 74′ contacting interconnect sites 724, 724′ on the image sensor die and contacting pads 844, 844′ on the device 82. In this example the interposed electrical device 82 has interconnect sites 924, 924′, and electrical connection of the interposed device with the support 90 is made by way of electrically conductive traces 94, 94′ contacting interconnect pads 924, 924′ on the image sensor die and contacting pads 944, 944′ on the support 90.

FIG. 10 illustrates an example of an optical sensor assembly in which an optical sensor die 122 is mounted over (not directly onto) a support 100, with an additional electrical device interposed between the optical sensor die and the substrate surface. In this example, the interposed electrical device constitutes a stack of die 1002, 1004 mounted onto and electrically connected to, a surface 101 of the support 100. That is, in this example the upper die 1004 in the stack (or the stack itself) constitutes a support. In this example a first die 1002 in the stack is mounted onto the support 100 surface using a die attach adhesive 1003 (such as a die attach film or a die attach epoxy, for example); and a second die 1004 in the stack is mounted onto the first die 1002 using a die attach adhesive 1005 (such as a die attach film or a die attach epoxy, for example). Also, in the example shown the first and second die in the stack are electrically interconnected die-to-die, and connected to interconnect pads 1006 on the circuitry at the surface 101 on the support 100, using traces 1008 of an interconnect material that is applied in a flowable form, in a manner similar to that described above for connection of the image sensor die to the sensor die mount side of the support. The die in the stack may have the same functionality (or example, they may be memory die), or they may have different functionalities; and the die may have the same or different dimensions. The stack may include more than two die; and, a single die may be mounted on the substrate in place of the stack. Interposed electrical device (or devices) may have dimensions smaller than a dimension of the overlying image sensor die, and in such embodiments the interconnect sidewall of the image sensor die may overhang the interposed device (or devices). FIG. 11 illustrates an example of an optical sensor assembly in which an optical sensor die 122 is mounted over (not directly onto) a support 110, and an additional electrical device constituting in this example a stack of devices 112, 114, is interposed between the optical sensor die and the substrate surface. In this example the interconnectedge of the optical sensor die 122 extends beyond, and overhangs, the edge of the interposed electrical device. In such embodiments pedestals of electrically conductive material may be formed in contact with electrical connection sites in the substrate, and the image sensor die may be electrically connected to the sites on the support by way of the pedestals. In the example shown in FIG. 11, pedestals 1146, 1146′ of electrically conductive material are formed at the sites 1144, 1144′ at the interconnect surface 111 of the underlying support 110, and the image sensor die 122 is electrically connected to the support by way of traces 1174, 1174′ of an electrically conductive material that is applied to or adjacent to the coated interconnectedge and sidewall and that make contact with the pedestals 1146, 1146′. The pedestals may be formed of any electrically conductive material that has suitable mechanical properties; formation of such pedestals is described, for example, in T. Caskey et al. U.S. application Ser. No. 12/124,097, referred to and incorporated herein by reference above.

FIG. 13A shows in a sectional view an example of a capacitance-based fingerprint sensor package according to an embodiment of the invention, in which a fingerprint sensor die is mounted onto and is electrically connected to a support. In this example a capacitance sensor die 1322 is mounted on the sensor die mount side of a package substrate 1310 using a die attach film 1321. The die 1322 is mounted with the active (sensor) front side facing away from the substrate 1310. Circuitry on the active side of the die includes an array of capacitance sensors 1326, and access and decoding circuitry 1325, 1325′.

A layer of electrically conductive material (a metal or metallization) on the substrate is patterned to form conductive traces, including bond pads 1312, 1312′. A dielectric layer 1311 such as a solder mask over the conductive traces has openings exposing the bond pads.

The capacitance sensor array 1326 may include an array of any of a variety of capacitance sensors, such as active capacitance sensors or passive capacitance sensors.

According to the invention, the fingerprint sensor die 1322 is electrically connected to the support by interconnect traces 1314, 1314′ of electrically conductive material that contacts and provides electrical continuity between interconnect die pads (e.g., pad 1324′) and corresponding sites in the support (e.g., bond pad 1312′).

Suitable electrically conductive materials include materials that can be applied in a flowable form and then cured or allowed to cure to form the electrically conductive traces. Such materials include, for example, electrically conductive polymers, including electrically conductive particulates (e.g., conductive metal particles) contained in a curable organic polymer matrix (for example, conductive (e.g., filled) epoxies, or electrically conductive inks); and include, for example, electrically conductive particulates delivered in a liquid carrier. The material may be applied by dispensing, or printing, or spraying, for example. Examples of suitable interconnect materials, and techniques for applying them, are described for example in T. Caskey et al. U.S. patent application Ser. No. 12/124,097, titled “Electrical interconnect formed by pulsed dispense”, which was filed May 20, 2008, and which is incorporated herein by reference. Conductive inks may be applied by aerosol spray, for example, and may following application be sintered or cured, according to the constitution of the particular ink. Particles in a carrier may be dispensed or applied by aerosol spray, for example, and may following application be sintered to form the electrically conductive traces.

Because the material making the interconnect traces are applied in a flowable form onto the surfaces over which the traces are made, the height of the interconnects above the front die surface is about the thickness of the traces where they pass from the die pads to and over the interconnect die edge; and this can be substantially less than the typical loop height of a wire-bond interconnect. Depending upon the rheological characteristics of the electrically conductive material, and upon the technique for depositing it, the trace can be very thin. For conductive inks deposited by aerosol spray, the deposited line of conductive material may range from as thin as about 10 nm or less to about 40 nm or greater, usually in a range about 5 um to about 20 um, and in some particular embodiments about 10 um. Additionally the traces rest firmly on the die surfaces, and so they are much less vulnerable than wire bonds to damage or distortion by contact during processing or during use.

FIG. 13B shows in a sectional view an example of a capacitance-based fingerprint sensor package according to another embodiment of the invention, in which a fingerprint sensor die is mounted onto and is electrically connected to a support generally as described above with reference to FIG. 13A. Here, a molding or encapsulation 1317 is formed at the die margins, covering the die pads and the interconnects and the upper surface of the support. The molding or encapsulation can serve to make the sensor package more rigid.

In these examples a mechanically and chemically protective layer is provided over the active surface of the die 1322; this provides a contact surface for the subject finger to rest upon or to sweep over, preventing or at least mitigating abrasion or degradation of the active surface of the die.

Useful materials for the protective layer include organic polymers and, for a conformal coating, suitable materials include organic polymers formed by vapor deposition. A particularly useful conformal coating may be a polymer of p-xylene or a derivative thereof, such as a polyxylylene polymer, e.g., a parylene C or a parylene N, or a parylene A.

The conformal coating is formed to a thickness at least sufficient to ensure that it has no openings through to the underlying surface; typically the thickness of the conformal coating may be in a range about 0.1 um to about 50 um. In particular embodiments where the conformal coating is a vapor deposited parylene, for example, the conformal coating may be applied at a rate about 10 Å per second, to a thickness in a range about 1 um to about 15 um, for example. Depending upon the particular material used for the protective coating, a greater thickness may be desired for increased mechanical protection.

In the example of FIG. 13B, the protective layer 1338 covers the front side of the die 1322; and the die pads either are left uncovered by the coating, or are exposed for electrical connection by making openings in the protective layer. Accordingly, in this configuration, the package height above the die front side consists of the sum of the thickness of the traces where they run from the die pads to and over the interconnect die edge, plus the thickness of the molding or encapsulation over the traces. The molding or encapsulation thickness over the traces depends upon properties of the particular molding compound or encapsulant; the thickness may range from about 5 um to about 30 um, in some examples about 25 um. Here, the molding or encapsulation and the protective coating provide for mechanical and chemical protection of the sensor.

In the example of FIG. 13A, the protective layer 1328 covers the front side of the die, the die sidewalls, the interconnects, and (as shown here) an upper surface of the support 1310. In the illustrated example, the protective layer is a conformal film. In this configuration no molding or encapsulation is required, and the package can be installed through a suitably dimensioned opening in the outer shell of the device in which it is used. The sensor package can if desired be situated about flush with or even projecting from the surface of the device, for ready touch access by the subject finger.

In both configurations the footprint of the sensor is nearly chip scale.

MEMS devices may be advantageously deployed in association with die that are electrically connected to a support by interconnect traces constructed by applying lines of electrically conductive material in a flowable form and then cured or allowed to cure to provide electrical continuity between interconnect die pads and corresponding sites in the support.

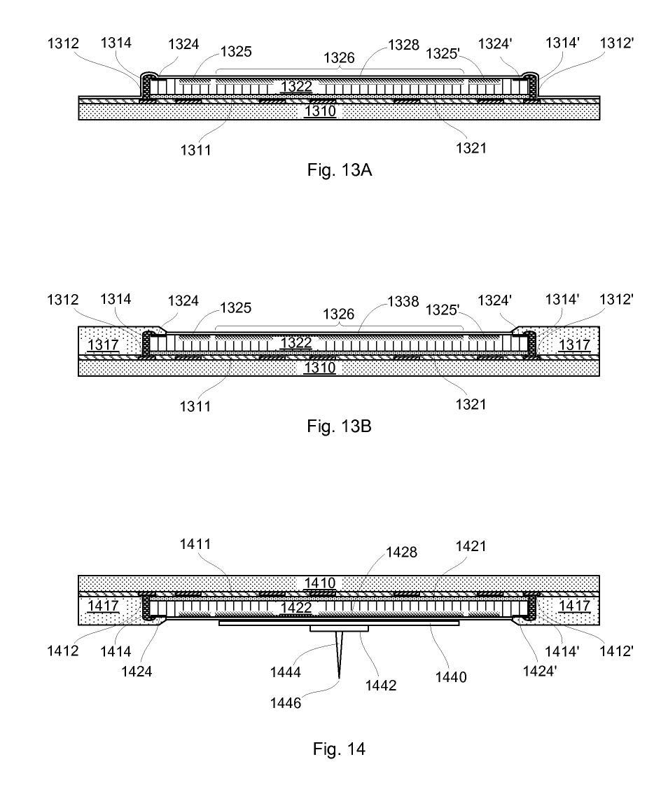

In one example, illustrated for example in FIG. 14, a MEMS device constituted a sensing element for a contact profilometer. The sensor die in this example is similar to the sensor die in FIG. 13B. Particularly, FIG. 14 shows in a sectional view an example of a profilometer sensor according to an embodiment of the invention. In this example the sensor die 1422 is mounted on the sensor die mount side of a package substrate 1410 using a die attach film 1421. The die 1422 is mounted with the active (sensor) front side facing away from the substrate 1410. Circuitry on the active side of the die includes an array of sensors 1426, which may for example be capacitance sensors, and, optionally, access and decoding circuitry.

A layer of electrically conductive material (a metal or metallization) on the substrate is patterned to form conductive traces, including bond pads 1412, 1412′. A dielectric layer 1411 such as a solder mask over the conductive traces has openings exposing the bond pads.

The sensor array 1426 may include an array of any of a variety of sensors, coupled to and sensitive to displacement or stress in a MEMS device 1440.

According to the invention, the sensor die 1422 is electrically connected to the support by interconnect traces 1414, 1414′ of electrically conductive material that contacts and provides electrical continuity between interconnect die pads (e.g., pad 1424′) and corresponding sites in the support (e.g., bond pad 1412′). Suitable electrically conductive materials are described above with reference to FIG. 13A, for example.

In this example, a stylus 1444 is mounted by way of a mount 1442 to a cantilever 1440. The cantilever is formed using MEMS (or nano-MEMS) fabrication techniques at or over the active surface of the die 1422. The cantilever may for example be rigidly attached at one or more points; or it may for example be set on pivots. Movement of part of the cantilever toward or away from the active sensing area of the die is reflected in a signal. The apparatus is arranged so that a tip 1446 of the stylus can be contacted with a surface to be profiled, and then swept over the surface or selectively tapped at various points on the surface. Variations in the contour of the surface result in variations in deflection of the cantilever, which are then sensed by the sensor die.

The active surface of the die in the example of FIG. 14 for example can be maneuvered very close to the surface being profiled; the drawings are not to scale and the stylus can be relatively much shorter.

Other embodiments are within the claims.

We claim:

1. A sensor die, comprising a semiconductor die having a front side, a back side, and sidewalls, the front side having an active surface comprising a sensor area, and interconnect pads arranged in an interconnect margin along at least one interconnectedge, the sensor die further comprising a conformal dielectric coating over the interconnectedge.

2. The sensor die of claim 1, further comprising a dielectric conformal coating over at least the sensor area.

3. The sensor die of claim 1, the active surface further comprising a peripheral circuit area.

4. The sensor die of claim 1 wherein the conformal dielectric coating over the interconnect edge comprises an organic polymer.

5. The sensor die of claim 2 wherein the dielectric conformal coating over at least the sensor area comprises an organic polymer.

6. The sensor die of claim 2 wherein the dielectric conformal coating over at least the sensor area comprises a polymer of p-xylene or a derivative thereof.

7. The sensor die of claim 2 wherein the dielectric conformal coating over at least the sensor area comprises a parylene C or a parylene N, or a parylene A.

8. The sensor die of claim 1 wherein the conformal dielectric coating over the interconnect edge comprises a polymer of p-xylene or a derivative thereof.

9. The sensor die of claim 2 wherein the dielectric conformal coating over at least the sensor area and the conformal dielectric coating over the interconnectedge comprise a similar material.

10. The sensor die of claim 2 wherein the dielectric conformal coating over at least the sensor area and the conformal dielectric coating over the interconnectedge comprise the same material.

11. The sensor die of claim 2 wherein the dielectric conformal coating over at least the sensor area and the conformal dielectric coating over the interconnectedge each comprises a polymer of p-xylene or a derivative thereof.

12. A sensor package, comprising a sensor die mounted over a support, wherein the sensor die comprises a semiconductor die having a front side, a back side, and sidewalls, the front side having an active surface comprising a sensor area and interconnect pads arranged in an interconnect margin along at least one interconnectedge, the sensor die further comprising a conformal dielectric coating over the interconnectedge; and wherein the sensor die is electrically connected to interconnect sites at a first surface of the support by traces of an electrically conductive material that is applied to or adjacent to the coated interconnectedge and sidewall, wherein a said trace makes contact with an exposed pad on the sensor die and with a site on the support.

13. The package of claim 12 wherein the electrically conductive material comprises a material that can be applied in a flowable form and then cured or allowed to cure to form the electrically conductive traces.

14. The package of claim 13 wherein the electrically conductive material comprises an electrically conductive polymer.

15. The package of claim 14 wherein the electrically conductive material comprises electrically conductive particulates contained in a curable organic polymer matrix.

16. The package of claim 15 wherein the particulates comprise conductive metal particles.

17. The package of claim 15 wherein the electrically conductive material comprises a conductive epoxy.

18. The package of claim 15 wherein the electrically conductive material comprises an electrically conductive ink.

19. The package of claim 12 wherein the electrically conductive material comprises an electrically conductive particulate delivered in a liquid carrier.

20. The package of claim 12 wherein the sensor die further comprises a dielectric conformal coating over at least the sensor area.

22. The package of claim 12 wherein the active surface of the sensor die further comprises a peripheral circuit area.

23. The package of claim 12 wherein the conformal dielectric coating over the interconnect edge comprises an organic polymer.

24. The package of claim 20 wherein the dielectric conformal coating over at least the sensor area comprises an organic polymer.

25. The package of claim 20 wherein the dielectric conformal coating over at least the sensor area comprises a polymer of p-xylene or a derivative thereof.

26. The package of claim 20 wherein the dielectric conformal coating over at least the sensor area comprises a parylene C or a parylene N, or a parylene A.

27. The package of claim 12 wherein the conformal dielectric coating over the interconnect edge comprises a polymer of p-xylene or a derivative thereof.

28. The package of claim 20 wherein the dielectric conformal coating over at least the sensor area and the conformal dielectric coating over the interconnectedge comprise a similar material.

29. The package of claim 20 wherein the dielectric conformal coating over at least the sensor area and the conformal dielectric coating over the interconnectedge comprise the same material.

30. The package of claim 20 wherein dielectric conformal coating over at least the sensor area and the conformal dielectric coating over the interconnectedge each comprises a polymer of p-xylene or a derivative thereof.

31. The package of claim 12 wherein the support comprises one of: a package substrate, an additional die, a printed circuit board, a leadframe, a glass plate.

32. The package of claim 31 wherein the support comprises one of: a BGA substrate, an “LGA”) substrate, or a flex tape substrate.

33. The package of claim 31 wherein the support comprises an additional die.

34. The package of claim 12 wherein the sensor die is mounted onto a surface of the support.

35. The package of claim 12 wherein an additional electrical device (such as an additional die) is interposed between the sensor die and the support.

36. The package of claim 35 wherein the sensor die is additionally electrically connected to circuitry in the additional electrical device.

37. The package of claim 35 wherein the interposed electrical device comprises an additional semiconductor die.

38. The package of claim 37 wherein the interposed electrical device comprises a stack of additional semiconductor die.

39. The package of claim 35 wherein the interposed electrical device comprises one of: a memory die, a processor such as a graphics processing unit, a wireless communication chip, a network access chip.

40. The package of claim 35 wherein circuitry in the interposed electrical device is electrically connected to circuitry in the support.

41. The package of claim 38 wherein two or more additional die in the stack are electrically interconnected.

42. The package of claim 38 wherein the stack of additional die is electrically connected to the support.

43. The package of claim 38 wherein the sensor die is electrically connected to interconnect sites on at least one of the additional die in the stack.

44. The package of claim 12 wherein an additional electrical device is mounted on and electrically connected to interconnect sites at a second surface of the support.

45. The package of claim 44 wherein the second surface and the first surface are areas of the same side of the support.

46. The package of claim 44 wherein the second surface and the first surface are areas of opposite sides of the support.

47. The package of claim 44 wherein the additional electrical device mounted on the second surface of the support comprises one of an additional die or stack of additional die or a semiconductor package.

48. A method for preparing a sensor die, comprising: providing a wafer having sensor circuitry formed on an active side thereof, cutting the wafer to form interconnect die edges and sidewalls, and forming a conformal dielectric coating over the front side of the cut wafer, including the interconnect edges.

49. The method of claim 48, further comprising thinning the wafer by removal of material from the wafer backside.

50. The method of claim 49 wherein cutting the wafer is carried out at least in part prior to thinning the wafer.

51. The method of claim 49 wherein thinning the wafer is carried out at least in part prior to cutting the wafer.

52. The method of claim 49 wherein the wafer is cut in at least two cutting procedures, and thinning the wafer is carried out at a time between the two cutting procedures.

53. The method of claim 48 wherein forming the dielectric coating comprises forming a polymer film by vapor deposition.

54. The method of claim 53 wherein forming the dielectric coating comprises forming a parylene film by vapor deposition.

55. A method for making a sensor package, including providing a die having a front side and a back side and sensor circuitry formed on the front side, the die having interconnect pads situated near an interconnect die edge; providing a support having connection sites at a first surface thereof; mounting the die over the first surface; applying a conformal dielectric coating over at least the interconnectedges; and electrically connecting the die to circuitry in the support, by applying a trace of an electrically conductive material to or adjacent to the coated interconnect edge in contact with an exposed pad on the die and with a connection site on the support.

56. The method of claim 55 wherein applying a conformal dielectric coating over at least the interconnect edges is carried out prior to mounting the die.

57. The method of claim 55 wherein applying a conformal dielectric coating over at least the interconnect edges is carried out after mounting the die.

58. The method of claim 55, further comprising applying a conformal dielectric coating over the front side of the sensor die.

59. The method of claim 58 wherein applying the conformal dielectric coating over the front side of the sensor die and applying a conformal dielectric coating over at least the interconnect edges are carried out concurrently.

60. The method of claim 55 wherein applying the conformal dielectric coating over at least the interconnect edges includes coating at least a portion of the interconnect pad, and further comprising forming an opening through the coating to expose the pad.

61. The method of claim 55 wherein mounting the sensor die over the first surface of the support comprises mounting the die onto the first surface of the support.

62. The method of claim 55 wherein mounting the sensor die over the first surface of the support comprises mounting an additional electrical device on the first surface of the support, and affixing the sensor die onto a surface of the additional electrical device.

63. The method of claim 55, further comprising mounting and electrically connecting an additional electrical device onto a second surface of the support.

64. The method of claim 63 wherein the second surface and the first surface are areas of the same side of the support.

65. The method of claim 63 wherein the second surface and the first surface are areas of opposite sides of the support.

66. The sensor die of claim 1, comprising a fingerprint sensor.

67. The sensor package of claim 12, comprising a fingerprint sensor.

68. The sensor package of claim 13, comprising a fingerprint sensor.

69. The sensor die of claim 1, comprising a profilometer.

70. The sensor package of claim 12, comprising a profilometer.

71. The sensor package of claim 13, comprising a profilometer.
